(19) United States
(12) Patent Application Publication
(10) Pub. No.: US 2011/0049663 A1
(43) Pub. Date: Mar. 3, 2011

(54) Structure of photodiode array

(76) Inventors: Wen-Long Chou, Chunan Jenn (TW); Ni-Ting Chu, Chunan Jenn (TW); Chiung-Jeng Wang, Chunan Jenn (TW)

(21) Appl. No.: 12/461,833

(22) Filed: Aug. 26, 2009

(51) Int. Cl. H01L 31/0224

(52) U.S. Cl. 257/446; 257/E31.124

(57) ABSTRACT

A structure of photodiode array includes a first electrode on which a plurality of second electrodes is arranged in a spaced manner forming an array and a plurality of isolation sections, which is each formed between adjacent ones of the spaced and arrayed second electrodes, whereby in carrying out tests of light currents, correct detection of the light currents can be realized to improve cross-talking between adjacent dodoes so as to effectively suppress interference of noise and alleviate the problem of low S/N ratio.

### FIELD OF THE INVENTION

The present invention relates to a structure of photodiode array, and in particular to a structure of photodiode array that allows for accurate detection of light current and improving cross-talking between adjacent diodes.

### BACKGROUND OF THE INVENTION

Photodiode arrays have been widely applied in electronic products. FIG. 5 of the attached drawings shows the structure of a conventional photodiode array. The conventional photodiode array structure, which is generally designated at 200, comprises a cathode 210 and a plurality of anodes 220. The anodes 220 are arranged in an array on the cathode 210. In this arrangement, the result of test of the light current through a single photodiode cell is susceptible to the influence caused by the light current through adjacent photodiode cells and this often causes an increase of the light current of the photodiode cell to be tested, affecting the accuracy of test.

In view of the problem, the present invention aims to provide a structure of a photodiode array that provides accurate test result so as to reduce the costs and enhance the performance.

### SUMMARY OF THE INVENTION

An objective of the present invention is to provide a structure of photodiode array, which allows for accurate detection of light current and improving cross-talking between adjacent diodes.

To realize the above objective, the present invention provides a structure of photodiode structure that comprises a first electrode; a plurality of second electrodes, which is arranged on the first electrode in a spaced manner to form an array; and a plurality of isolation sections, which is each formed between adjacent second electrodes to block light diffusion current flowing therethrough. With such an arrangement, accurate detection of the light currents can be realized to improve cross-talking between adjacent dodoes, so as to effectively suppress interference of noise and alleviate the problem of low S/N (signal to noise) ratio, enhancing accuracy of devices and stability of function, and reducing flaw rate of product.

### BRIEF DESCRIPTION OF THE DRAWINGS

The present invention will be apparent to those skilled in the art by reading the following description of a preferred embodiment thereof with reference to the drawings, in which:

FIG. 1 is a perspective view of a structure of photodiode array in accordance with the present invention;

FIG. 2 is a top plan view of the structure of photodiode array in accordance with the present-invention;

FIG. 3 is a cross-sectional view of the structure of photodiode array in accordance with the present invention;

FIG. 4 show curves of light current obtained with the photodiode array structures of the present invention and a structure of a conventional photodiode array, in which L1 indicates Comparison Example 1 of the conventional structure; and L2, L3, and L4 respectively indicate Embodiments 1, 2, and 3, all being embodiments of the present invention; and

FIG. 5 is a schematic view of a structure of a conventional photodiode array.

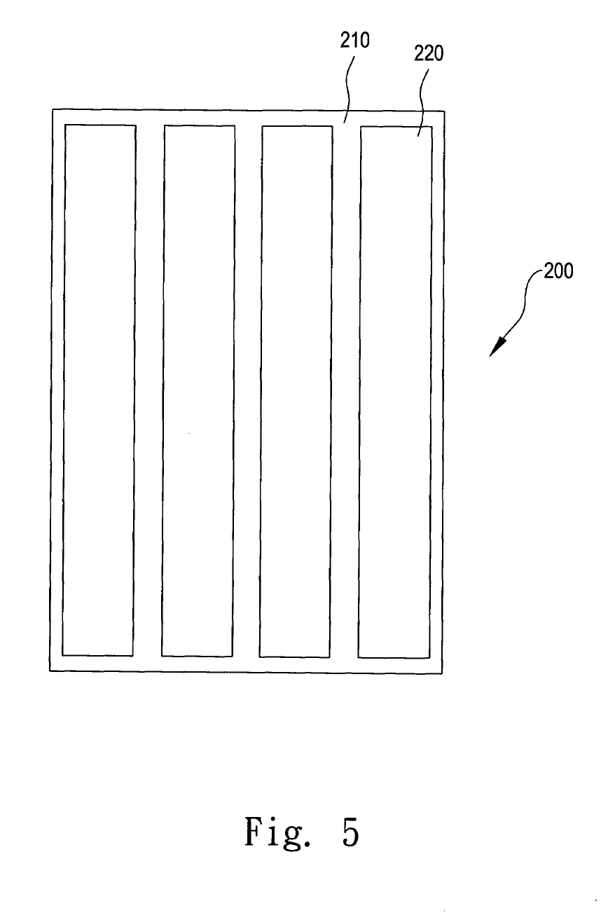

### DETAILED DESCRIPTION OF THE PREFERRED EMBODIMENT

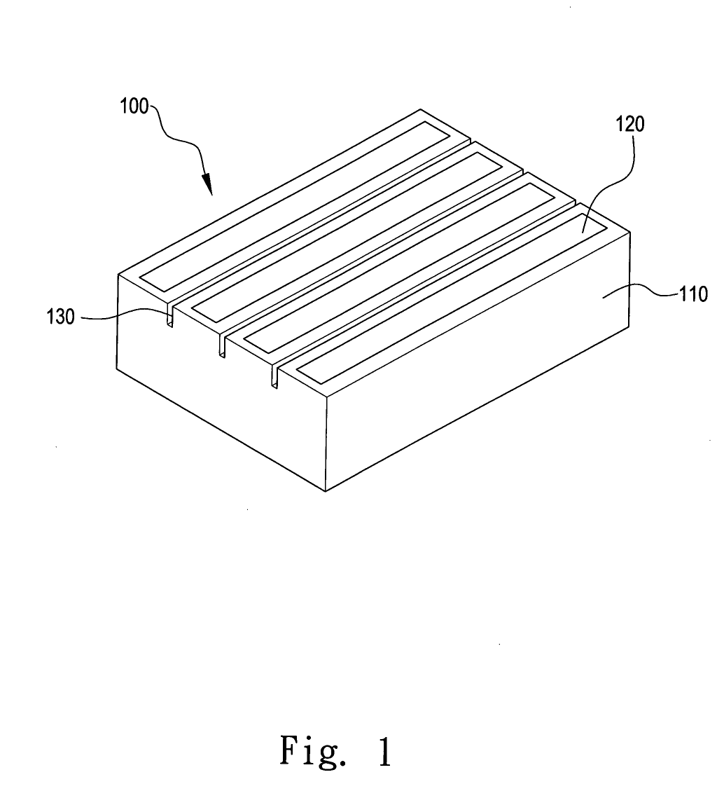

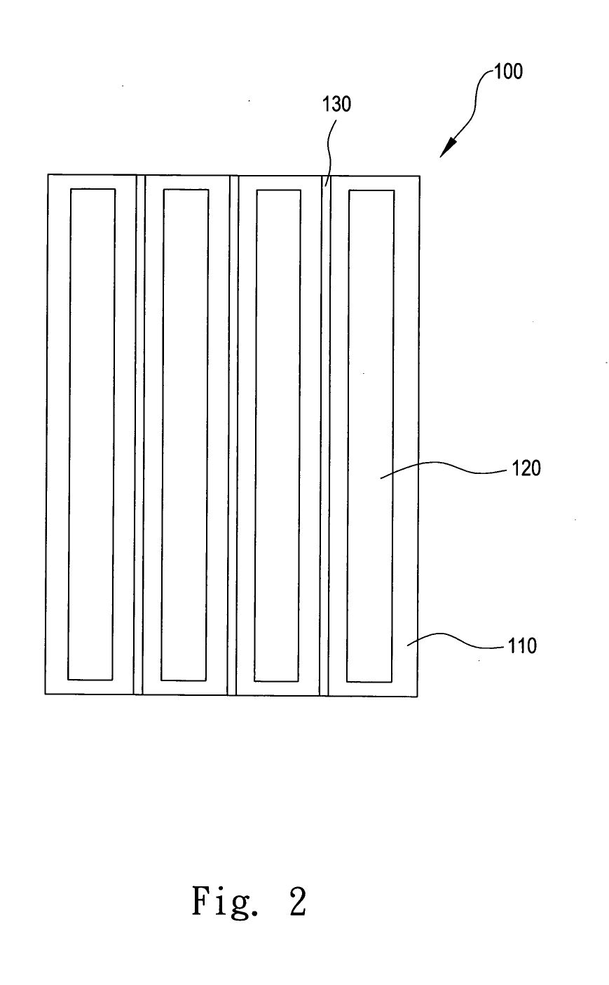

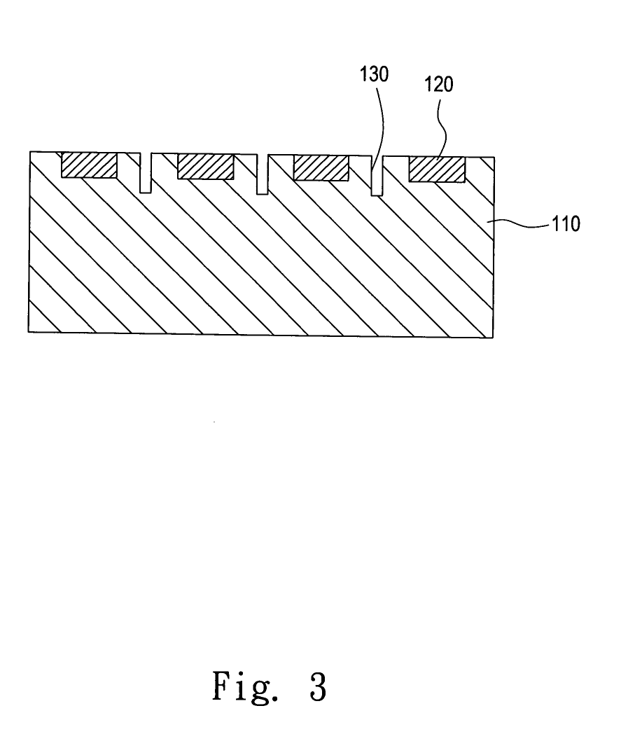

With reference to the drawings and in particular to FIGS. 1-3, which show, respectively a perspective view, a top plan view, and a cross-sectional view of a structure of photodiode array in accordance with the present invention, the structure of photodiode array in accordance with the present invention, generally designated with reference numeral 100, comprises a first electrode 110, a plurality of second electrodes 120, and a plurality of isolation sections 130 for realizing correct detection of light current in the test of light current.

The second electrodes 120 are arranged on the first electrode 1 in a spaced manner and forming an array. In an embodiment, the first electrode 110 serves as a cathode and the second electrodes 120 are anodes. In an alternative embodiment, the first electrode 110 serves as an anode and the second electrodes 120 are cathodes. In the embodiment illustrated in the drawings, the first electrode 110 is taken as a cathode.

Each isolation section 130, which is formed as a notch having a predetermined depth in the first electrode 110, is arranged between adjacent second electrodes 120, whereby the light diffusion current induced in the test of light current of the photodiode array structure 100 is blocked by a barrier formed by the isolation section 130 so as to provide correct result of detection of the light current and alleviate cross-talking between adjacent diodes. The depth of the isolation sections 130 is set to be greater than a depth of the second electrodes and preferably ranges from 5 to 550 micrometers.

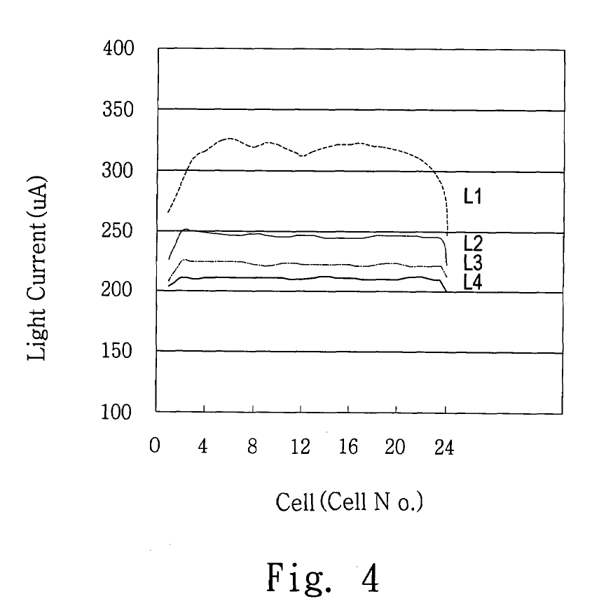

Referring to FIG. 4, curves of light current obtained with the photodiode array structure of the present invention are shown, which are obtained with dices containing photodiode array structures made with the same process and subjected to half cutting as indicated in Table 1.

TABLE 1

| | Embodiment | | | Comparison |
|---|---|---|---|---|
| | 1 | Embodiment 2 | Embodiment 3 | Example 1 |
| Depth | 50 | 100 | 150 | 0 |
| (micron) | | | | |

Tests of light current are then carried out on the above provided dices that are subjected to half cutting and contain photodiode array structures and the results of the tests are listed in Tables 2-5. The curves of FIG. 4 are plotted in accordance with the data listed in Tables 2-5, in which L1 indicates Comparison Example 1 of the conventional structure, L2 indicates Embodiment 1 of the present invention, L3 indicates Embodiment 2 of the present invention, and L4 indicates Embodiment 3 of the present invention.

TABLE 2
Comparison Example 1

| Cell | Light Current (μA) |
|---|---|
| 1 | 264.5 |
| 2 | 287.5 |
| 3 | 308.7 |
| 4 | 315.2 |
| 5 | 322.5 |
| 6 | 325.5 |
| 7 | 322.0 |
| 8 | 319.0 |
| 9 | 322.0 |
| 10 | 321.0 |
| 11 | 316.0 |
| 12 | 312.0 |
| 13 | 315.7 |
| 14 | 318.9 |
| 15 | 321.5 |
| 16 | 320.9 |
| 17 | 322.2 |
| 18 | 320.0 |
| 19 | 318.9 |
| 20 | 316.8 |
| 21 | 312.7 |
| 22 | 308.7 |
| 23 | 300.0 |
| 24 | 248.0 |
| Average | 310.84 |
| Standard Deviation | 18.89 |
| Percentage | 6.1% |

TABLE 3
Embodiment 1

| Cell | Light Current (μA) |
|---|---|
| 1 | 225.5 |
| 2 | 249.0 |
| 3 | 249.0 |
| 4 | 248.5 |
| 5 | 247.5 |
| 6 | 246.5 |
| 7 | 246.5 |
| 8 | 247.0 |
| 9 | 246.0 |
| 10 | 245.0 |
| 11 | 245.0 |
| 12 | 246.5 |
| 13 | 245.5 |
| 14 | 244.0 |
| 15 | 244.0 |
| 16 | 243.5 |
| 17 | 244.0 |
| 18 | 246.5 |
| 19 | 246.5 |
| 20 | 246.5 |
| 21 | 246.0 |
| 22 | 244.5 |
| 23 | 245.0 |
| 24 | 222.0 |
| Average | 244.17 |
| Standard Deviation | 6.49 |
| Percentage | 2.7% |

TABLE 4
Embodiment 2

| Cell | Light Current (μA) |
|---|---|
| 1 | 213.0 |
| 2 | 228.5 |
| 3 | 228.5 |
| 4 | 229.0 |
| 5 | 229.0 |
| 6 | 229.0 |
| 7 | 228.5 |
| 8 | 226.5 |
| 9 | 225.5 |
| 10 | 227.0 |
| 11 | 227.5 |
| 12 | 226.5 |
| 13 | 226.5 |
| 14 | 226.0 |
| 15 | 226.5 |
| 16 | 226.5 |
| 17 | 226.0 |
| 18 | 226.5 |
| 19 | 228.0 |
| 20 | 228.0 |
| 21 | 226.0 |
| 22 | 226.0 |
| 23 | 226.0 |
| 24 | 212.5 |
| Average | 225.98 |
| Standard Deviation | 4.22 |
| Percentage | 1.9% |

TABLE 5
Embodiment 3

| Cell | Light Current (μA) |
|---|---|
| 1 | 206.5 |
| 2 | 212.5 |
| 3 | 212.0 |
| 4 | 212.5 |
| 5 | 212.5 |
| 6 | 212.5 |
| 7 | 212.5 |
| 8 | 212.5 |
| 9 | 212.5 |
| 10 | 212.5 |
| 11 | 212.0 |
| 12 | 212.0 |
| 13 | 213.0 |
| 14 | 213.5 |
| 15 | 213.0 |
| 16 | 212.5 |
| 17 | 212.0 |
| 18 | 212.0 |
| 19 | 212.0 |
| 20 | 212.0 |
| 21 | 213.5 |
| 22 | 213.5 |
| 23 | 212.0 |
| 24 | 203.5 |
| Average | 211.88 |
| Standard Deviation | 2.22 |
| Percentage | 1.0% |

The results of tests shown in Tables 2-5 and FIG. 4 indicate that the light current detected with the photodiode array structure in accordance with the present invention have a lower value of standard deviation as compared to the light current obtained with a photodiode array structure that is not provided with the isolation sections, and the standard deviation of the light current obtained with a photodiode array structure having isolation sections of a great depth is lower than the light current obtained with a photodiode array structure having isolation sections of a small depth. In other words, when the second electrodes of the photodiode array structure are used as an active area, the isolation sections arranged between adjacent second electrodes may function as barriers for blocking light, whereby in receiving light with the photodiode array structure, the light diffusion current induced can be blocked by the barriers formed by the isolation sections thereby providing the photodiode array structure with more stabilized detection of the current.

To summarize, the structure of photodiode array in accordance with the present invention comprises a first electrode on which a plurality of second electrodes is arranged in a spaced manner forming an array and a plurality of isolation sections, which is each formed between adjacent ones of the spaced and arrayed second electrodes, whereby in carrying out tests of light currents, accurate detection of the light currents can be realized to improve cross-talking between adjacent dodoes, effectively suppress interference of noise, and thus alleviates the problem of low S/N (signal to noise) ratio, enhances accuracy of devices and stability of function, reduces flaw rate of product, and eliminates the concern about probability of matching a light source, so as to simplify the test process and reduce the cost of test.

Although the present invention has been described with reference to the preferred embodiment thereof, it is apparent to those skilled in the art that a variety of modifications and changes may be made without departing from the scope of the present invention which is intended to be defined by the appended claims.

What is claimed is:

1. A structure of photodiode array, comprising:
a first electrode;
a plurality of second electrodes, which is arranged on the first electrode in a spaced manner to form an array; and
a plurality of isolation sections, which is each formed between adjacent second electrodes to block light diffusion current flowing therethrough.

2. The structure of photodiode array as claimed in claim 1, wherein the first electrode comprises an anode and wherein the second electrodes comprise cathodes.

3. The structure of photodiode array as claimed in claim 1, wherein the first electrode comprises a cathode and wherein the second electrodes comprise anodes.

4. The structure of photodiode array as claimed in claim 1, wherein the isolation sections have a depth greater than a depth of the second electrodes.

5. The structure of photodiode array as claimed in claim 1, wherein the isolation section has a depth of 5-550 micrometers.
